(19) United States
(12) Patent Application Publication
(10) Pub. No.: US 2014/0070243 A1
(43) Pub. Date: Mar. 13, 2014

(54) LIGHT-EMITTING DEVICE AND METHOD OF MANUFACTURING THE SAME

(71) Applicant: ILJIN-LED CO., LTD., Ansan-Si (KR)

(72) Inventors: Chan Soo KIM, Suwon-Si (KR); Dong woo KIM, Seoul (KR); Keuk KIM, Seongnam-Si (KR); Chong Mann KOH, Seoul (KR)

(73) Assignee: ILJIN-LED CO., LTD., Ansan-Si (KR)

(21) Appl. No.: 14/020,692

(22) Filed: Sep. 6, 2013

(30) Foreign Application Priority Data
Sep. 7, 2012 (KR) 10-2012-0099299

(51) Int. Cl. H01L 27/15

(52) U.S. Cl. CPC H01L 27/156
USPC 257/89; 438/29

(57) ABSTRACT

Provided is a light-emitting device including a light-emitting cell formed on one surface of a substrate, wherein the light-emitting cell comprises a plurality of semiconductor layers and emits light of a certain wavelength; and a wavelength conversion layer formed on the other surface of the substrate and to a certain height of the side of the substrate, wherein the wavelength conversion layer converts a wavelength of light emitted from the light-emitting cell.

### CROSS-REFERENCE TO RELATED APPLICATION

This application claims priority to Korean Patent Application No. 10-2012-0099299 filed on Sep. 7, 2012 and all the benefits accruing therefrom under 35 U.S.C. §119, the contents of which are incorporated by reference in their entirety.

### BACKGROUND

The present disclosure relates to a light-emitting device, and more particularly, to a light-emitting device and a method of manufacturing the same that may enhance light extraction efficiency and thus enhance luminance.

In general, nitride such as GaN, AlN, and InGaN has excellent thermal stability and a direct transition-type energy band and thus takes center stage as a material for a photoelectronic device, recently. In particular, since at room temperature, an energy band gap of GaN is 3.4 eV and that of InGaN is 1.9 eV to 2.8 eV depending on the ratio of In to Ga, the nitride may be used for a high-temperature high-output device.

A light-emitting device using a nitride semiconductor such as GaN and InGaN generally has a N-type semiconductor layer, an active layer, and a P-type semiconductor layer stacked on its substrate, and includes an N-type electrode and a P-type electrode that are respectively connected to the N-type semiconductor layer and the P-type semiconductor layer. If a certain current is applied to the N-type electrode and the P-type electrode, an electron provided from the N-type semiconductor layer is re-combined with a hole provided from the P-type semiconductor layer, at the active layer, and the light-emitting device emits light having a wavelength corresponding to an energy gap. Such a light-emitting device is disclosed in Korean laid-open patent publication No 2008-0050904.

In the case of a general white light-emitting device, semiconductor layers including an active layer are formed on a substrate such as a sapphire substrate and a phosphor layer is formed on the semiconductor layers. In this case, the phosphor layer is deformed or damaged due to heat generated from the semiconductor layers, which leads to a decrease in luminance.

Moreover, light emitted from the active layer is emitted in various directions other than an emission surface. That is, the light emitted from the active layer is emitted, for example, to the emission surface of the P-type electrode as wells to a substrate which has a direction opposite to the emission surface. Thus, the light emitted from the active layer passes through the N-type semiconductor layer and the P-type semiconductor layer several times and is then emitted to the emission surface, and the wavelength of the light is converted and emitted through a phosphor formed over the emission surface.

However, since light is absorbed into a material having a band gap lower than that of the light, light that passes through a semiconductor layer using InGaN having, for example, a band gap of 2.8 eV is absorbed into the semiconductor layer if it has a band gap higher than that. That is, since a blue light having a band gap of approximately 2.9 eV that is emitted from the active layer passes through the N-type semiconductor layer and the P-type semiconductor layer several times, light having a band gap higher than those is absorbed into them and thus light extraction efficiency decreases and luminance reduces.

### SUMMARY

The present disclosure provides a light-emitting device and a method of manufacturing the same that may enhance light extraction efficiency and thus enhance luminance.

The present disclosure also provides a light-emitting device and a method of manufacturing the same that may enhance light extraction efficiency by forming a wavelength conversion layer that is spaced apart from semiconductor layers.

The present disclosure also provides a light-emitting device and a method of manufacturing the same that may enhance light extraction efficiency by allowing light emitted in directions other than a desired emission surface to have a band gap lower than that of a semiconductor layer by changing the wavelength of the light.

The present disclosure also provides a light-emitting device and a method of manufacturing the same that change the wavelength of light emitted in directions other than a desired emission surface by arranging a wavelength conversion layer on a surface other than the desired emission surface.

In accordance with an exemplary embodiment, a light-emitting device includes a substrate on one surface of which a plurality of light-emitting cells are formed, wherein the plurality of light-emitting cells comprises a plurality of semiconductor layers and emits light of a certain wavelength; a plurality of cut portions formed on the other surface of the substrate at a certain depth; and a wavelength conversion layer formed on the other surface of the substrate and the plurality of cut portions, wherein the wavelength conversion layer converts a wavelength of light emitted from the light-emitting cell.

The substrate may include a transparent substrate.

The cut portion may be formed to overlap with a scribe line for dividing at least one light-emitting cell.

The wavelength conversion layer may include at least one of a phosphor layer and a quantum dot layer.

In accordance with another exemplary embodiment, a light-emitting device includes a light-emitting cell formed on one surface of a substrate, wherein the light-emitting cell comprises a plurality of semiconductor layers and emits light of a certain wavelength; and a wavelength conversion layer formed on the other surface of the substrate and to a certain height of the side of the substrate, wherein the wavelength conversion layer converts a wavelength of light emitted from the light-emitting cell.

The substrate may include a transparent substrate.

The wavelength conversion layer may include at least one of a phosphor layer and a quantum dot layer.

The light-emitting device may further include a reflective layer formed on the wavelength conversion layer to reflect light of which a wavelength is converted by the wavelength conversion layer.

The wavelength conversion layer may convert light emitted from the light-emitting cell into light having a low band gap.

The light-emitting device may further include a support layer formed on the reflective layer.

The support layer may be formed of metal.

The support layer may include a heat sink.

The light-emitting device may further include a second wavelength conversion layer formed on the light-emitting cell.

The light-emitting device may further include a second wavelength conversion layer formed at a certain distance from the light-emitting cell.

In accordance with still another exemplary embodiment, a method of manufacturing a light-emitting device includes stacking a plurality of semiconductor layers on one surface of a substrate and forming a plurality of light-emitting cells; forming a plurality of cut portions on the other surface of the substrate at a certain depth; and forming a wavelength conversion layer on the plurality of cut portions and on the other surface of the substrate including the plurality of cut portions.

The method may further include forming a reflective layer on the wavelength conversion layer.

The method may further include forming a support layer on the reflective layer.

### BRIEF DESCRIPTION OF THE DRAWINGS

Exemplary embodiments can be understood in more detail from the following description taken in conjunction with the accompanying drawings, in which:

FIGS. 1 and 2 respectively are a plane view and a sectional view of a light-emitting device according to an embodiment;

FIG. 3 is a sectional view of a light-emitting device according to another embodiment;

FIGS. 4 and 5 respectively are a plane view and a sectional view of a light-emitting device according to another embodiment;

FIG. 6 is a schematic diagram for explaining an optical path of a light-emitting device according to another embodiment;

FIG. 7 is a sectional view of a light-emitting device according to another embodiment; and

FIGS. 8 and 9 are sectionals views of packages to which light-emitting devices according to embodiments are applied.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration. Like reference numerals refer to like elements throughout.

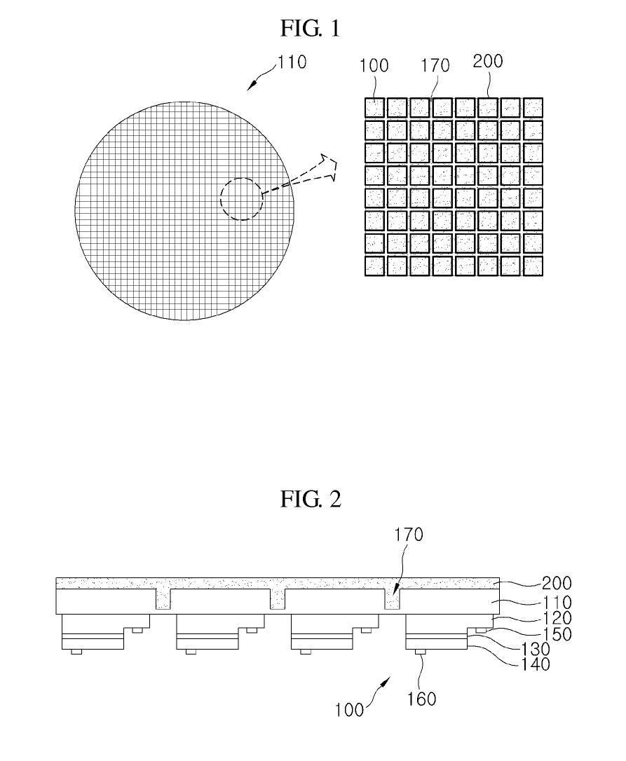

FIGS. 1 and 2 respectively are a plane view and a sectional view of a light-emitting device according to an embodiment.

Referring to FIGS. 1 and 2, a light-emitting device according to an embodiment may include a substrate 110; a plurality of light-emitting cells 100 that each includes a plurality of semiconductors formed on one surface of the substrate 110, emits light of a certain wavelength, and is spaced apart from each other; a cut portion 170 that is formed at a certain depth on a certain area of the back surface of the substrate 110 where the light-emitting cell 100 is not formed; and a wavelength conversion layer 200 that is formed on the back surface of the substrate 110 and the side of the substrate 110 through the cut portion 170 and converts the wavelength of the light emitted from the light-emitting cell 100. Moreover, each of the plurality of light-emitting cells 100 may include a first semiconductor layer 120, an active layer 130, and a second semiconductor layer 140 that are sequentially formed on the substrate 110; and a first and a second electrode 150 and 160 that are formed through etching and exposure of a portion of the active layer 130 and a portion of the second semiconductor layer 140 and are respectively formed on a first and a second semiconductor layer 120 and 140. Here, the plurality of light-emitting cells 100 may be serial-connected, parallel-connected, or serial-parallel-connected. That is, a first electrode 150 of one light-emitting cell 100 may be serial-connected, parallel-connected, or serial-parallel-connected to a first or a second electrode 150 or 160 of another light-emitting cell by using, for example, a wiring (not shown).

The substrate 110 indicates a typical wafer for manufacturing a light-emitting device and may use a material that is suitable for allowing nitride semiconductor single crystal to grow. For example, the substrate 110 may use any one of Al2O3, SiC, ZnO, Si, GaAs, GaP, LiAl2O3, BN, AlN and GaN. Moreover, it is possible to use a transparent substrate or an opaque substrate according to an emission direction of light. That is, if light is emitted to the substrate 110 and thus passes through the substrate 110, the transparent substrate may be used, and if light is emitted to the opposite side, the opaque substrate may be used.

The first semiconductor layer 120 may be an N-type semiconductor that is doped with N-type dopant, and may thus supply an electron to the active layer 130. For example, the first semiconductor layer 120 may use an InGaN layer which is doped with Si. However, the present invention is not limited thereto and various semiconductor materials may be used. That is, nitride such as GaN, InN, and AlN (III group to V group) and a compound that is formed by mixing such nitride at a certain ratio may be used. On the other hand, the light-emitting cell 100 may form a buffer layer (not shown) including AlN or GaN in order to alleviate a lattice mismatch with the substrate 110 before forming the first semiconductor layer 120 on the substrate 110. Moreover, an undoped layer (not shown) may be formed on the buffer layer. The undoped layer may be formed as a layer without doping dopant, such as an undoped GaN layer.

The active layer 130 has a certain band gap, forms a quantum well and thus is an area where an electron and a hole are re-combined. The active layer 130 may be formed as multiple quantum well (MQW) where a quantum well layer and a barrier layer are alternately stacked. For example, the active layer 130 of the MQW may be formed by alternately stacking InGaN and GaN or by alternately stacking AlGaN and GaN. Here, since a light-emitting wavelength that is generated by combing an electron and a hole varies depending on a type of a material that forms the active layer 130, it is possible to adjust a semiconductor material to be included in the active layer 130 according to a desired wavelength. That is, the wavelength of light generated from the active layer 130 may be adjusted by adjusting the amount of In in the quantum well layer. For example, by using a phenomenon where a light-emitting wavelength lengthens since a band gap decreases as the amount of In in the InGaN quantum well layer increases, it is possible to emit light from an ultraviolet area to all visible areas including blue, green, and red. Moreover, it is possible to change the light-emitting wavelength by adjusting the thickness of the quantum well layer and for example, if the thickness of the InGaN quantum well layer increases, a band gap decreases and thus it is possible to emit red light. In addition, it is also possible to obtain white light by using the MQW. That is, it is possible to obtain white light as a whole if configuring blue light, green light, and red light by differently adjusting the amount of In at least every one layer of multiple InGaN quantum well layers. However, the present embodiment exemplifies a case where the active layer 130 emits blue light. On the other hand, the active layer 130 is formed without an area where the first electrode 150 is formed.

The second semiconductor layer 140 may be a semiconductor layer on which a P-type dopant is doped, and may thus supply a hole to the active layer 130. For example, the second semiconductor layer 140 may use an InGaN layer on which Mg is doped. However, the present invention is not limited thereto and various semiconductor materials may be used. That is, nitride such as GaN, InN, and AlN (III group to V group) and a compound that is formed by mixing such nitride at a certain ratio may be used. Moreover, the second semiconductor layer 140 may be formed as a single layer or multiple layers. On the other hand, the second semiconductor layer 140 is formed without an area where the first electrode 150 is formed.

The first and the second electrode 150 and 160 may be formed by using a conductive material, and may be formed as a single layer or multiple layers by using, for example, a metal material such as Ti, Cr, Au, Al, Ni, and Ag, or alloys thereof. Here, the second electrode 160 may be formed in plural depending on an electrode pattern for current diffusion. On the other hand, a reflective electrode (not shown) may be formed on the second semiconductor layer 140 so that power supplied through the second electrode 160 is uniformly supplied to the second semiconductor layer 140 and light emitted to the second electrode 160 is reflected. That is, since the second semiconductor layer 140 has, for example, a vertical resistance of several to tens of and, for example, a horizontal resistance of several kΩ to several MΩ, a current does not flow in a horizontal direction but flows only in a vertical direction. Thus, since a current does not flow throughout the second semiconductor 140 if power is locally supplied to the second semiconductor 140, it is possible to form a conductive layer on the second semiconductor layer 140 so that the current may flow throughout the second semiconductor layer 140. In this case, it is possible to form the conductive layer with a material having high reflectivity in order to reflect light that is generated from the active layer 130 and emitted to the second electrode 160. That is, it is possible to form a reflective electrode having high conductivity and high reflectivity on the second semiconductor layer 140. The reflective electrode may be formed of, for example, Ag, Ni, Al, Ph, Pd, Ir, Ru, Mg, Zn, Pt, Au, and alloys thereof, and may have reflectivity that is equal to or higher than 90%.

The wavelength conversion layer 200 is arranged in order to change the wavelength of light that is generated from the light-emitting cell 100 and emitted toward the substrate 110. That is, the wavelength conversion layer 200 of the light-emitting device according to the present embodiment is spaced apart from the semiconductor layers of the light-emitting cell 100. When a phosphor is formed to be in contact with the semiconductor layer of the light-emitting cell 100, the phosphor is typically deformed or damaged due to heat generated from the semiconductor layer, which leads to a decrease in luminance. However, since the wavelength conversion layer 200 of the present embodiment is spaced apart from the semiconductor layers of the light-emitting cell 100, it is possible to prevent the wavelength conversion layer from becoming deformed or damaged and thus prevent a decrease in luminance. Moreover, since the wavelength conversion layer 200 is also formed on the side of the substrate 110, a wavelength conversion area may become wide. In addition, since the wavelength conversion layer 200 is formed to a certain height of the side of the substrate 110 and not formed on the side of the first semiconductor layer 120, it is possible to prevent the wavelength conversion layer 200 from becoming thermally deformed or damaged.

Such a wavelength conversion layer 200 converts, for example, blue light having a wavelength of 420 nm to 480 nm that is generated from the light-emitting cell 100, into light having a wavelength higher than that, such as green light having a wavelength of 490 nm to 550 nm, yellow light having a wavelength of 560 nm to 580 nm, red light having a wavelength of 590 nm to 630 nm or mixed light thereof. In this case, it is possible to mix light having a plurality of wavelengths and thus emit white light. Such a wavelength conversion layer 200 may be formed on the back surface and side of the substrate 110 and to this end, it is possible to form the wavelength conversion layer 200 at a wafer level. For example, as shown in FIGS. 1 and 2, after forming the cut portion 170 on the back surface of the substrate 110 on which the plurality of light-emitting cells 100 is spaced apart from one another, it is possible to form the wavelength conversion layer 200 on the back surface of the substrate 110 including the cut portion 170. Here, the cut portion 170 may be a scribe line that cuts the substrate 110 in order to split the plurality of light-emitting cells 100. Moreover, the wavelength conversion layer 200 may be formed of various materials that convert the wavelength of incident light, and may be formed by using, for example, a phosphor layer, a quantum dot layer, etc. That is, it s possible to form the phosphor layer by applying phosphor containing paste to the wavelength conversion layer 200 and it is possible to form the quantum dot layer by applying quantum dot containing paste to the wavelength conversion layer 200. When forming the phosphor layer by using the phosphor paste, the phosphor paste may have a viscosity of approximately 500˜10000 cps by mixing, for example, phosphor powder with transparent thermosetting polymer resin in order to evenly form the phosphor layer and prevent phosphor powder from becoming unevenly distributed during the process. Here, the thermosetting polymer resin may be silicon based polymer resin or epoxy based polymer resin. Moreover, it is possible to manufacture and use phosphor paste in which the weight ratio of the phosphor powder to the thermosetting polymer resin is between 0.5 and 10. If blue light for example is emitted from the light-emitting cell 100, the wavelength conversion layer 200 using the phosphor layer may convert the blue light into at least one of green light, yellow light, red light and mixed light thereof that have a wavelength longer than that of the blue light. A material such as YBO₃:Ce, Tb; BaMgAl₁₀O₁₇:Eu, or Mn; (SrCaBa)(Al, Ga)₂S₄:Eu may be used as green phosphor for changing the blue light to the green light. Moreover, a material that includes one or more of Y, Lu, Sc, La, Gd, and Sm; one or more of Al, Ga, and In; and garnet based phosphor activated with Ce may be used as yellow phosphor for changing the blue light to the yellow light. In addition, a material such as Y₂O₂S:Eu, Bi; YVO₄:Eu, Bi; Srs:Eu, SrY₂S₄:Eu, or CaLa₂S₄:Ce.(Ca, Sr)S:Eu may be used as red phosphor for changing the blue light to the red light. However, in addition to the materials above, any phosphor that converts the blue light into at least one of the yellow light, the red light, and the green light may be used. Of course, it is possible to emit mixed light, especially white light by mixing these phosphors. Moreover, the quantum dot layer may be formed by using a quantum dot and organic binder. The quantum dot layer may also convert the blue light into any one of the yellow light, the red light, the green light, and mixed light thereof that have a wavelength longer than that of the blue light. As a quantum dot material, as a red quantum dot material for example, II group to IV group compound semiconductor nano crystal, such as CdS, CdSe, CdTe, ZnS, ZnSe, ZnTe, HgS, HgSe, or HgTe, III group to V group compound semiconductor nano crystal, or mixtures of these materials may be used.

As described above, for the light-emitting device according to an embodiment, the wavelength conversion layer 200 that converts the wavelength of light emitted from the light-emitting cell 100 is formed on the back surface and side of the substrate 110 to be spaced apart from the semiconductor layers of the light-emitting cell 100. Moreover, in order to form the wavelength conversion layer 200 at the wafer level, after forming the cut portion 170 on the back surface of the substrate 110 on which the plurality of light-emitting cells 100 is spaced apart from one another, it is possible to form the wavelength conversion layer 200 on the back surface of the substrate 110 including the cut portion 170. Thus, since the wavelength conversion layer 200 is spaced apart from the semiconductor layer of the light-emitting cell 100, it is possible to prevent the phosphor from becoming deformed or damaged due to heat generated from the semiconductor and thus prevent the luminance of the light-emitting device from decreasing.

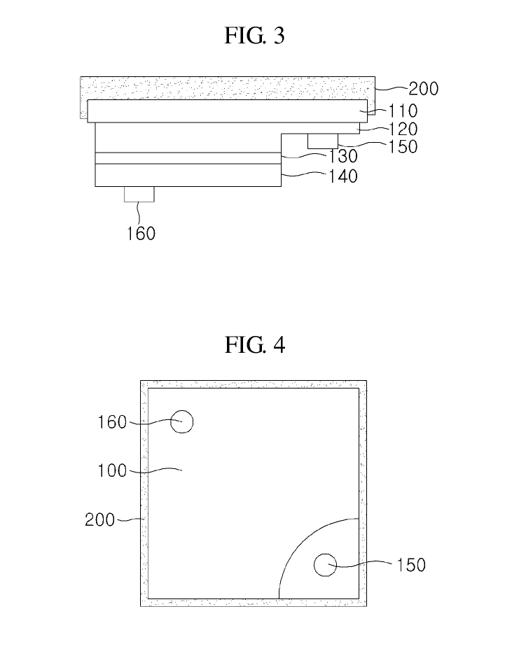

Moreover, the light-emitting device according to embodiments may also be manufactured on a light-emitting cell 100 basis. That is, although the light-emitting device according to an embodiment has the wavelength conversion layer 200 that is formed on the back surface and side of the substrate 110 on which the plurality of light-emitting cells 100 are formed, the wavelength conversion layer 200 may also be formed on the back surface and side of the substrate 110 on which one light-emitting cell 100 is formed as shown in FIG. 3. The light-emitting device based on one light-emitting cell 100 may be manufactured by scribing the light-emitting device having the plurality of light-emitting cells 100 described in FIGS. 1 and 2 on a light-emitting cell 100 basis. Moreover, such a light-emitting device may be bonded to a sub mount substrate having a certain pad by using a bump.

On the other hand, light emitted from the light-emitting device is emitted in various directions other than a desired emission surface. That is, the light emitted from the active layer 130 is emitted to, for example, an emission surface of the second electrode 160 and to the substrate 110 that is opposite thereto. Thus, the light emitted from the active layer passes through the semiconductor layers several times and then is emitted to the emission surface. In this case, since light is absorbed into the semiconductor layers, light extraction efficiency decreases and luminance reduces. A light-emitting device according to another embodiment for solving the drawbacks will be described with reference to FIGS. 4 to 6.

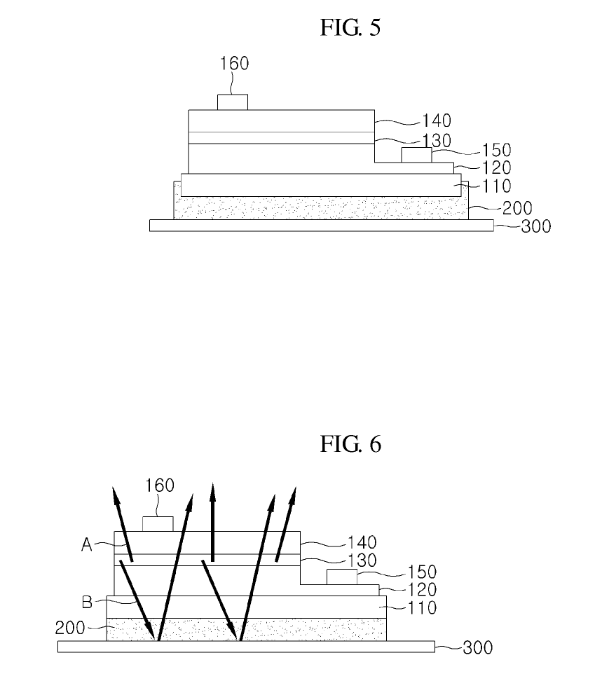

FIGS. 4 and 5 respectively are a plane view and a sectional view of a light-emitting device according to another embodiment, and FIG. 6 is a schematic diagram for explaining an optical path of a light-emitting device according to another embodiment. In the following, descriptions that have been made above will not be provided.

Referring to FIGS. 4 and 5, a light-emitting device according to another embodiment may include a light-emitting cell 100 that is formed as a plurality of semiconductor layers on the substrate 110 and emits light of a certain wavelength, a wavelength conversion layer 200 that is formed on the back surface and side of the substrate 110 and converts the wavelength of light in order to convert the band gap of the light emitted from the light-emitting cell 100, and a reflective layer 300 that is formed on the wavelength conversion layer 200 and reflects the light emitted from the light-emitting cell 100. Moreover, the light-emitting cell 100 may include a first semiconductor layer 120, an active layer 130, and a second semiconductor layer 140 that are sequentially formed on the substrate 110; and a first and a second electrode 150 and 160 that are formed through etching and exposure of a portion of the active layer 130 and a portion of the second semiconductor layer 140 and are respectively formed on a first and a second semiconductor layer 120 and 140. Moreover, a transparent electrode (not shown) may be formed on the second semiconductor layer 140 so that power supplied through the second electrode 160 is evenly supplied to the second semiconductor layer 140 and the light generated from the active layer 130 may be well transmitted. The transparent electrode may be formed of a transparent conductive material, such as ITO, IZO, ZnO, RuOx, TiOx, IrOx, etc.

The wavelength conversion layer 200 is arranged to convert the wavelength of light that is generated from the light-emitting cell 100 and emitted to a reflective layer 300, and thus change a band gap. The light generated from the active layer 130 of the light-emitting cell 100 may be emitted upwardly through the second semiconductor layer 140, and may be emitted downwardly through the first semiconductor layer 120. In this case, the light emitted to under the light-emitting cell 100 may be reflected by the reflective layer 300 made of, for example, a metal material and may thus be emitted upwardly through the light-emitting cell 100. However, since the light is absorbed into the plurality of semiconductor layers of the light-emitting cell 100, namely, the first semiconductor layer 120, the active layer 130, and the second semiconductor layer 140 while passing through the semiconductor layers, light extraction efficiency decreases. That is, since light is absorbed into a material that has a band gap lower than that of the light, the light is absorbed into the semiconductor layers if the band gap of the light is higher than those of the semiconductor layers. For example, if blue light having a wavelength of 420 nm to 480 nm is emitted from the light-emitting cell 100, the blue light has a band gap of approximately 2.9 eV. In addition, in a case where a material forming the semiconductor layers is InGaN, InGaN has a band gap of approximately 2.8 eV. Thus, the blue light is absorbed into the semiconductor layers while passing the semiconductor layers. Thus, light that is reflected from the lower part and emitted upwardly experiences more light loss while passing through many semiconductor layers, as compared to the light that is emitted upwardly. However, since the present embodiment forms the wavelength conversion layer 200 on the back surface and side of the substrate 110 opposite to a desired emission surface and coverts the wavelength of light passing through the wavelength conversion layer 200 so that the wavelength conversion layer 200 has a band gap lower than those of the semiconductor layers, light B that is reflected from the lower part and emitted upwardly as well as light A emitted upwardly are not lost and thus it is possible to enhance light extraction efficiency. For example, the wavelength conversion layer 200 converts blue light having a wavelength of 420 nm to 480 nm that is generated from the light-emitting cell 100, into light having a wavelength higher than that, such as green light having a wavelength of 490 nm to 550 nm, yellow light having a wavelength of 560 nm to 580 nm, red light having a wavelength of 590 nm to 630 nm or mixed light thereof. If the blue light is converted to a color light having a wavelength higher than that of the blue light, a band gap becomes low accordingly. This is because the band gap becomes low as a wavelength becomes long. For example, the green light has a band gap of approximately 2.17 eV to 2.5 eV, the yellow light has a band gap of approximately 2.11 eV to 2.17 eV, and the red light has a band gap of approximately 1.65 eV to 2.01 eV. Moreover, the wavelength conversion layer 200 may be formed of various materials that change the wavelength of incident light and may be formed by using, for example, a phosphor layer, a quantum dot layer, etc. That is, it s possible to form the phosphor layer by applying phosphor containing paste to the wavelength conversion layer 200, it is possible to form the quantum dot layer by applying quantum dot containing paste to the wavelength conversion layer 200, or it is possible to form a quantum dot layer, in which a quantum dot containing organic material is formed, between two transparent plates.

The reflective layer 300 may be formed of a material having high reflectivity in order to upwardly reflect light that is generated from the light-emitting cell 100, emitted downwardly, and converted in wavelength by the wavelength conversion layer 200. The reflective layer 300 may be formed of, for example, Ag, Ni, Al, Ph, Pd, Ir, Ru, Mg, Zn, Pt, Au, and alloys thereof, and may have reflectivity that is equal to or higher than 90%. The reflective layer 300 may be deposited on the wavelength conversion layer 200 at the wafer level or may be the cup bottom of a package on which the light-emitting cell 100 is held. In this case, the cup bottom of the package may be made of metal that has high reflectivity.

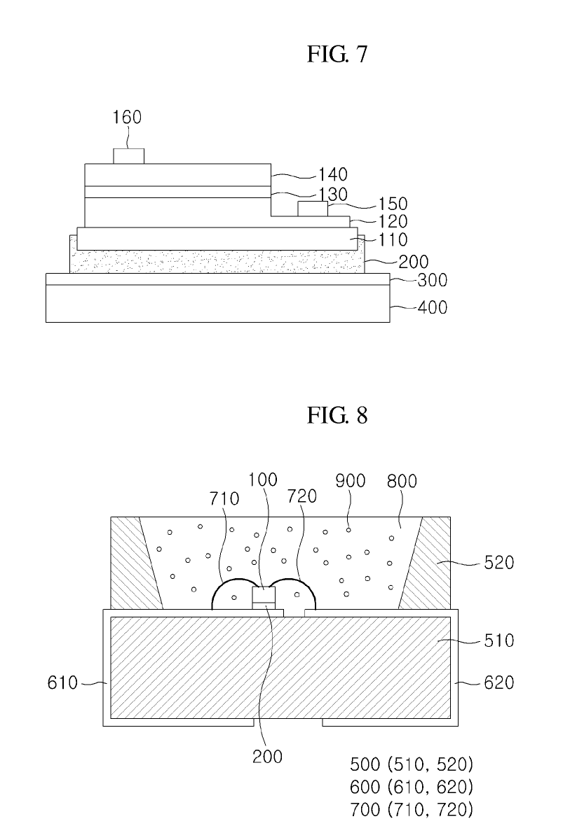

Moreover, as shown in FIG. 7, a support layer 400 may be formed on the reflective layer 300. That is, the reflective layer 300, the wavelength conversion layer 200, and the light-emitting cell 100 may be formed on the support layer 400, and the reflective layer 300 may be adhered to the support layer 400 by using an adhesive such as epoxy. Such a support layer 400 may be implemented by using various shapes and materials that may support the light-emitting cell 100, and may be manufactured by using, for example, a metal material. If the support layer 400 is manufactured by using a metal material, it is possible to easily emit heat generated from the light-emitting cell 100. Moreover, in order to more easily emit heat, a heat sink of a protrusion structure may be formed on the back surface of the support layer 400. Since due to the heat sink, the surface area of the support layer 400 widens and thus a contact area with the atmosphere widens, it is possible to more effectively radiate heat.

FIG. 8 is a sectional view of a light-emitting device package using a light-emitting device according to an embodiment.

Referring to FIG. 8, the light-emitting device package according to the present embodiment includes a package body 500, a lead frame 600 that is exposed from the package body 500 and protrudes outwardly, a wavelength conversion layer 200 that is formed on a certain area of the lead frame 600, a light-emitting cell 100 that is arranged on the wavelength conversion layer 200 and emits light, a wire 700 for electrically connecting the light-emitting cell 100 to the lead frame 600, a molding unit 800 that seals the light-emitting cell 100, and phosphors 900 that are arranged in the molding unit. Here, in addition to the package body 500 to which the light-emitting cell 100 is attached, a body including slug, a substrate, and a mold cup may be used, but the package body 500 will be described for example.

The package body 500 includes a housing 510 that supports the lead frame 600 and holds the light-emitting cell 100, and a reflector that is formed on the housing 510 and forms an opening through which light generated from the light-emitting cell 100 is emitted. Such a package body 500 may be manufactured by a transfer molding technique by using epoxy mold compound (EMC) which is formed by adding white pigment to thermosetting resin, such as epoxy resin, and thus the housing 510 and the reflector 520 may be integrally manufactured. That is, the support layer 400 of the light-emitting device according to the present embodiment may be the housing 510 of the package body 500. In other words, the housing 510 may function as the support layer 400. Of course, the housing is manufactured separately from the support layer 400 and a light-emitting device including the support layer 400 may be held on the housing 510. On the other hand, the reflector 520 includes a reflective surface that is protruded upwardly from the top of the housing 510. A reflective material may be applied to the reflective surface. In this case, it is possible to adjust a height of the reflective surface of at least one area of the reflector 520, and in this case, it is possible to adjust an emission range of light generated from the light-emitting cell 100. Moreover, the reflective surface may be formed internally at an angle. On the other hand, the shape of the reflector 520 may vary to be able to adjust an emission range of light emitted from the light-emitting cell 100 according to the use of a light-emitting apparatus as well as a circular shape and a quadrilateral shape.

The lead frame 600 is used to supply power from an external source to the light-emitting cell 100 and includes a first and a second lead frame 610 and 620 that are respectively formed on opposite sides. The lead frame 600 is supported on the housing 510 and may separate the housing 510 from the reflector 520. That is, the first and the second lead frame 610 and 620 are spaced apart from each other and extended from the upper side of the housing 510 to one and the other sides of the package body 500. Here, a part on which the light-emitting cell 100 is held, such as the first lead frame 610 may work as the reflective layer 300 of the light-emitting device. That is, it is possible to use the housing 510 and the first lead frame 610 as the support layer 400 and the reflective layer 300, respectively without separately forming the support layer 400 and the reflective layer 300 in the light-emitting device that needs the support layer 400, the reflective layer 300, the wavelength conversion layer 200, and the light-emitting cell 100. However, the lead frame 600 and the reflective layer 300 may be separately manufactured and the light-emitting device including the reflective layer 300 may be held on the lead frame 600.

The wire 700, 710, and 720 electrically connects the light-emitting cell 100 to the lead frame 600. The wire 700 may be formed of gold (Au) or aluminum (Al). The first wire 710 may electrically connect the second electrode 160 of the light-emitting cell 100 to the first lead frame 610 and the second wire 720 may electrically connect the first electrode 150 of the light-emitting cell 100 to the second lead frame 620.

The molding unit 800 plays a roll in sealing the light-emitting cell 100 and fixing the wire 700 that is connected to the light-emitting cell 100. Moreover, the molding unit 800 may also function as a lens that collecting light generated from the light-emitting cell 100. Since the molding unit 800 needs to transmit the light generated from the light-emitting cell 100 to the outside, it is formed of transparent resin such as epoxy resin or silicon resin. Moreover, the molding unit may further include a refractive index adjuster (not shown). As the refractive index adjuster, sapphire powder may be used. On the other hand, in addition to the refractive index adjuster, diffusing agent (not shown) may be added in order to evenly emit light by further diffusing light, which is emitted from the light-emitting cell 100, by using scattering. As the diffusing agent, BaTiO₃, TiO₂, Al₂O₃, SiO₂, etc. may be used. Moreover, a phosphor 900 may added to the molding unit 800.

The phosphor 900 absorbs at least a portion of the light generated from the light-emitting cell 100, and emits light having a wavelength different from that of the absorbed light. In this case, the phosphor 900 changes the wavelength of the light emitted from the light-emitting cell 100 to an emission surface and emits the changed light. The phosphor 900 selectively changes the wavelength of the light that is wavelength-changed by the wavelength conversion layer 200 arranged at a part facing the emission surface, namely, the lower part of the light-emitting cell 100 and that is emitted through the light-emitting cell 100, and emits the changed light. In an embodiment, the phosphor 900 changes the blue light generated from the light-emitting cell 100 into white light. To this end, it is possible to use a yellow phosphor and a red phosphor. In this case, since the light emitted through the wavelength conversion layer 200 is already wavelength-changed by the wavelength conversion layer 200, the phosphor 900 changing the converted light into white light may further be included. Moreover, as the phosphor 900, it is possible to use the phosphor used for the wavelength conversion layer 200 or it is possible to use a yellow phosphor or a red phosphor that is different therefrom. Moreover, it is possible to enhance a color rendering index (CRI) by making the phosphor concentration in the molding unit 800 different from that of the wavelength conversion layer 200.

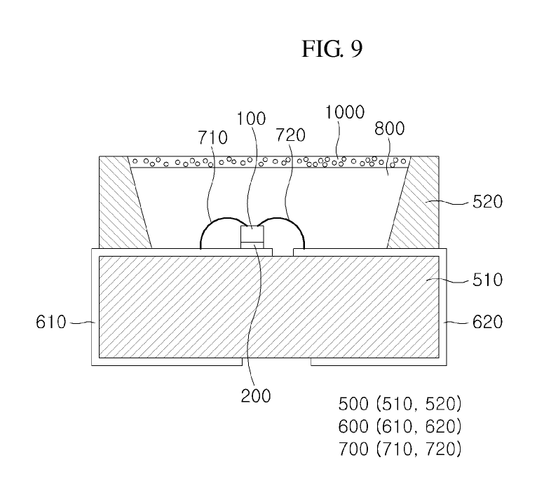

FIG. 9 is a sectional view of a light-emitting device package according to another embodiment, and a second wavelength conversion layer 1000 is formed on a molding unit 800. That is, the first wavelength conversion layer 200 may be formed under the light-emitting cell and the second wavelength conversion layer 1000 may be formed on the molding unit 800 that is formed to cover the light-emitting cell 100. In this case, the second wavelength conversion layer may also be formed by using phosphor paste in the same way as the first wavelength conversion layer 200, or may be formed by using a quantum dot. Moreover, it is possible to enhance a color rendering index (CRI) by making the phosphor concentration in the molding unit 800 different from that of the wavelength conversion layer 200.

According to the embodiments, the wavelength conversion layer that converts the wavelength of light emitted from the light-emitting cell is spaced apart from the semiconductor layers of the light-emitting cell and is formed on the back surface and side of the substrate. Moreover, the wavelength conversion layer may be formed at the wafer level, and after forming the cut portion on the back surface of the substrate on which the plurality of light-emitting cells are formed, it is possible to form the wavelength conversion layer on the back surface of the substrate including the cut portion.

Thus, since the wavelength conversion layer is spaced apart from the light-emitting cell, it is possible to prevent a phosphor from becoming deformed or damaged due to heat generated from the semiconductor when the phosphor is in contact with the semiconductor layer of the light-emitting cell, and thus it is possible to prevent the luminance of the light-emitting device from decreasing. Moreover, since the wavelength conversion layer is formed at the wafer level, it is possible to enhance process efficiency.

Moreover, according to the embodiments, by forming the wavelength conversion layer on an area other than a desired emission surface of the light-emitting cell, the wavelength of light that is generated from the light-emitting cell and emitted to a part other than the emission surface is converted and emitted to the emission surface. That is, the wavelength conversion layer converts light so that the light has a wavelength higher than that of the light generated from the light-emitting cell, and lowers a band gap accordingly.

By converting the band gap of light emitted to a part other than the desired emission surface to be lower than those of the semiconductor layers of the light-emitting cell and reflecting the converted light to the emission surface, the light is not absorbed into the semiconductor layer of the light-emitting cell but is emitted to the emission surface. Thus, it is possible to enhance light extraction efficiency and thus enhance luminance.

Moreover, since the wavelength conversion layer is formed to be equal to or lower than the height of the semiconductor layers on the side of the light-emitting cell, it is possible to increase a wavelength conversion area and thus enhance light extraction efficiency.

Although the technical spirit of the present invention has been described with reference to the specific embodiments, it is not limited thereto. Therefore, it will be readily understood by those skilled in the art that various modifications and changes can be made thereto without departing from the spirit and scope of the present invention defined by the appended claims.

What is claimed is:

1. A light-emitting device comprising:
a substrate on one surface of which a plurality of light-emitting cells are formed, wherein the plurality of light-emitting cells comprises a plurality of semiconductor layers and emits light of a certain wavelength;
a plurality of cut portions formed on the other surface of the substrate at a certain depth; and
a wavelength conversion layer formed on the other surface of the substrate and the plurality of cut portions, wherein the wavelength conversion layer converts a wavelength of light emitted from the light-emitting cell.

2. The light-emitting device of claim 1, wherein the substrate comprises a transparent substrate.

3. The light-emitting device of claim 1, wherein the cut portion is formed to overlap with a scribe line for dividing at least one light-emitting cell.

4. The light-emitting device of claim 3, wherein the wavelength conversion layer comprises at least one of a phosphor layer and a quantum dot layer.

5. A light-emitting device comprising:
a light-emitting cell formed on one surface of a substrate, wherein the light-emitting cell comprises a plurality of semiconductor layers and emits light of a certain wavelength; and
a wavelength conversion layer formed on the other surface of the substrate and to a certain height of the side of the substrate, wherein the wavelength conversion layer converts a wavelength of light emitted from the light-emitting cell.

6. The light-emitting device of claim 5, wherein the substrate comprises a transparent substrate.

7. The light-emitting device of claim 5, wherein the wavelength conversion layer comprises at least one of a phosphor layer and a quantum dot layer.

8. The light-emitting device of claim 5, further comprising a reflective layer formed on the wavelength conversion layer to reflect light of which a wavelength is converted by the wavelength conversion layer.

9. The light-emitting device of claim 8, wherein the wavelength conversion layer converts light emitted from the light-emitting cell into light having a low band gap.

10. The light-emitting device of claim 8, further comprising a support layer formed on the reflective layer.

11. The light-emitting device of claim 10, wherein the support layer is formed of metal.

12. The light-emitting device of claim 10, wherein the support layer comprises a heat sink.

13. The light-emitting device of claim 8, further comprising a second wavelength conversion layer formed on the light-emitting cell.

14. The light-emitting device of claim 8, further comprising a second wavelength conversion layer formed at a certain distance from the light-emitting cell.

15. A method of manufacturing a light-emitting device, the method comprising:
stacking a plurality of semiconductor layers on one surface of a substrate and forming a plurality of light-emitting cells;
forming a plurality of cut portions on the other surface of the substrate at a certain depth; and
forming a wavelength conversion layer on the plurality of cut portions and on the other surface of the substrate including the plurality of cut portions.

16. The method of claim 15, further comprising forming a reflective layer on the wavelength conversion layer.

17. The method of claim 16, further comprising forming a support layer on the reflective layer.
